(19) United States
(12) Patent Application Publication
(10) Pub. No.: US 2012/0269305 A1
(43) Pub. Date: Oct. 25, 2012

(54) BANG-BANG OFFSET CANCELLATION (AUTOZERO)

(75) Inventors: John Hogeboom, Ottawa (CA); Pat Hogeboom-Nivera, Ottawa (CA)

(73) Assignee: STMicroelectronics (Canada) Inc., Nepean (CA)

(21) Appl. No.: 13/450,181

(22) Filed: Apr. 18, 2012

Related U.S. Application Data
(60) Provisional application No. 61/477,984, filed on Apr. 21, 2011.

(51) Int. Cl. H03D 1/04

(52) U.S. Cl. 375/346

(57) ABSTRACT

A receive channel offset correction scheme utilizes “eye edge” samplers and demultiplexers already present and essential for operation of the CDR algorithm, and adds only simple word-rate logic, with no new analog circuitry. The result is the ability to precisely determine the offset polarity as well as to get an approximate immediate measure of the offset magnitude. The offset detected includes all of the analog circuitry in the channel, including the samplers themselves.

### RELATED APPLICATION

The present invention claims priority from U.S. Provisional Patent Application Ser. No. 61/477,984 filed Apr. 21, 2011, and is incorporated herein by reference in its entirety for all purposes as if fully set forth herein.

### FIELD OF THE INVENTION

The present invention is related to receivers, and more particularly to a receive channel offset correction scheme.

### BACKGROUND OF THE INVENTION

It is important to as nearly as possible cancel any voltage offset because any net offset directly reduces the sensitivity of the receiver by requiring a larger signal to reliably detect either the ‘0’ bits or the ‘1’ bits depending on the polarity of the offset. In SerDes (Serializer-Deserializer) applications, a so-called “Bang-Bang” CDR (Clock and Data Recovery) algorithm is often used for alignment of the receiver's is internal data sampling clock with the incoming serial data stream. This is a digital algorithm that accumulates a running count of the number of instances where an “edge” sample taken midway between two “data” samples mismatches the later of the two samples, minus the number of instances where it mismatches the earlier sample. Only transitions carry timing information, and only when there is an intermediate transition will successive samples be different, hence, indicative of the position of the transition. The idealized eye diagrams in FIG. 1 and FIG. 3 show a typical series of signal traces. Some traces, those associated with no transition between the adjacent data bits depicted, go straight through at either a low or a high level, some (not shown) may change just before or just after the two bits but be the same for both bits, but ones that change from low to high or from high to low between the two data bits are the ones of primary interest. Such traces provide information on whether the zero-crossing is before or after the mid-point between the data sampling points, or some nearby point if an additional timing offset is applied between edge and center sampling times to position the center samples more optimally. When the mismatch count between late sample and early sample reaches some specific preset threshold value, the sampling point timing will be adjusted in the corresponding direction by one minimum sized timing step. This is the basic bang-bang algorithm.

### SUMMARY OF THE INVENTION

According to the present invention, a receive channel offset correction scheme utilizes “eye edge” samplers and demultiplexers already present and essential for operation of the CDR algorithm, and adds only simple word-rate logic, with no new analog circuitry. The result is the ability to precisely determine the offset polarity as well as to get an approximate immediate measure of the offset magnitude. The offset detected includes all of the analog circuitry in the channel, including the samplers themselves, which other analog techniques usually miss. If there are odd and even samplers, independent detection for each is easily obtained. Only the edge-sampling path offset is detected; however, offset for the center-eye samplers (also including its entire analog path), can be obtained by swapping the roles of the center and edge channels. This swap can be automated to limit its duration to under the maximum needed for the CDR to track 0.1 unit intervals with nominal performance settings.

### BRIEF DESCRIPTION OF THE DRAWINGS

FIGS. 1 and 3 show eye diagrams as are known in the art;

FIG. 2 shows a top level receiver architecture with offset cancellation according to an embodiment of the present invention;

FIG. 4 is an eye diagram showing the statistic imbalance in function of the offset; and

FIG. 5 is a block diagram of the non-linear offset regulator loop.

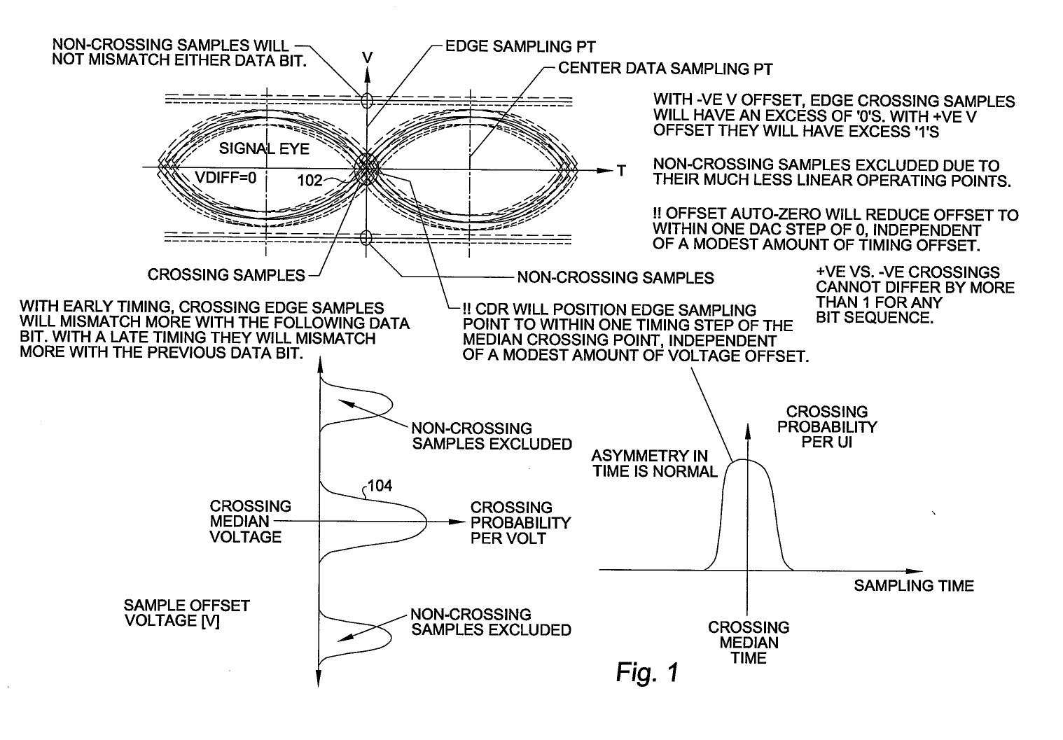

### DETAILED DESCRIPTION

The traces have statistical variation in both the voltage (vertical) dimension due to voltage noise from reflections and cross-talk, and in the timing (horizontal) dimension due to jitter on the input signal and on the receiver clocks. For little or no voltage offset and with the CDR adjusting edge timing toward the horizontal mid-point of the crossover region as indicated by the central ellipse 102, the traces pass equally to the left (early) and right (late) of the edge sampling point giving an average difference count of near zero. If the voltage offset is zero the sampling point will be near the middle of the dense crossover region, so small changes in timing will result in large immediate changes in the early vs. late counts, causing an immediate strong response to re-center the sampling time. If there is significant voltage offset, the edge sampling point will be near the top or bottom of the ellipse, or even outside, in which case response will be reduced or eliminated for small variations in timing, thereby reducing CDR effectiveness.

The traces also pass equally above and below the slicing level giving a near equal number of ‘0’ samples and ‘1’ samples at the edge sampling point. If there is a small offset voltage, which will move the input signal up or down relative the slicing level, as mentioned above there will still be a balance in number of traces passing to the left and right, but less density in crossovers near the slicing level. However, more importantly for offset correction there will be more traces passing above than below, or more below than above, hence a rapidly varying count difference between ‘0’s and ‘1’s as offset varies. Just like the bang-bang CDR algorithm, an equivalent bang-bang offset recovery or correction algorithm can be implemented by appropriate accumulation of the ‘0’ vs. ‘1’ count difference and adjustment of offset correction by a voltage step each time the count exceeds a preset threshold. Furthermore, just as a non-centered offset voltage reduces timing detection sensitivity, misalignment of the CDR algorithm reduces offset detection sensitivity. Hence, adjustments done by each algorithm optimize the effectiveness and accuracy of the other algorithm but with no first-order interaction.

A key property of the bang-bang offset auto-zero algorithm is that it uses all of the same circuitry used for the data path whose offset is to be zeroed, not separate information from separate offset circuitry which would not have identical offset. All of the circuitry of the analog signal path is included, with the only discrepancy being that the final sampling latches used for offset detection are the edge samplers, so the center samplers may have slightly different offset not visible to the primary control loop. The mismatch between identical samplers should be relatively minor, in part due to the significant gain in the path prior to the samplers, particularly when small signal amplitudes are expected, including the shared limiting amplifiers immediately before the sampling latches. Furthermore, if necessary, the difference between individual samplers can be measured directly in several ways using the receiver circuitry itself, and if necessary can be corrected by adding further offset insertion points besides the common point near the front-end. By adjusting such individual offsets for minimum BER (Bit Error Rate) under low signal conditions where BER is significant, optimum individual offset corrections can be applied and optimized.

The diagrams immediately below the double-eye diagram at the top show the statistical nature of the number of traces that fall at different locations in both the vertical (voltage) and horizontal (sampling time) directions near the edge sampling point. For example, the portion of the curve to the left 104 shows the density of traces vs. slicing threshold voltage near this point. If the slicing threshold is high, most traces will pass below the threshold so will result in a ‘0’ bit being sampled. If the threshold is low most bits sampled will be ‘1’. If the slicing threshold is exactly at the median level within the distribution curve, exactly an equal number of ‘0’s and ‘1’s will be detected, the condition that the auto-zero algorithm seeks. It seeks this point by moving the slicing threshold voltage up if more ‘1’s than ‘0’s are counted in any particular interval, and moving it down if more ‘0’s than are counted.

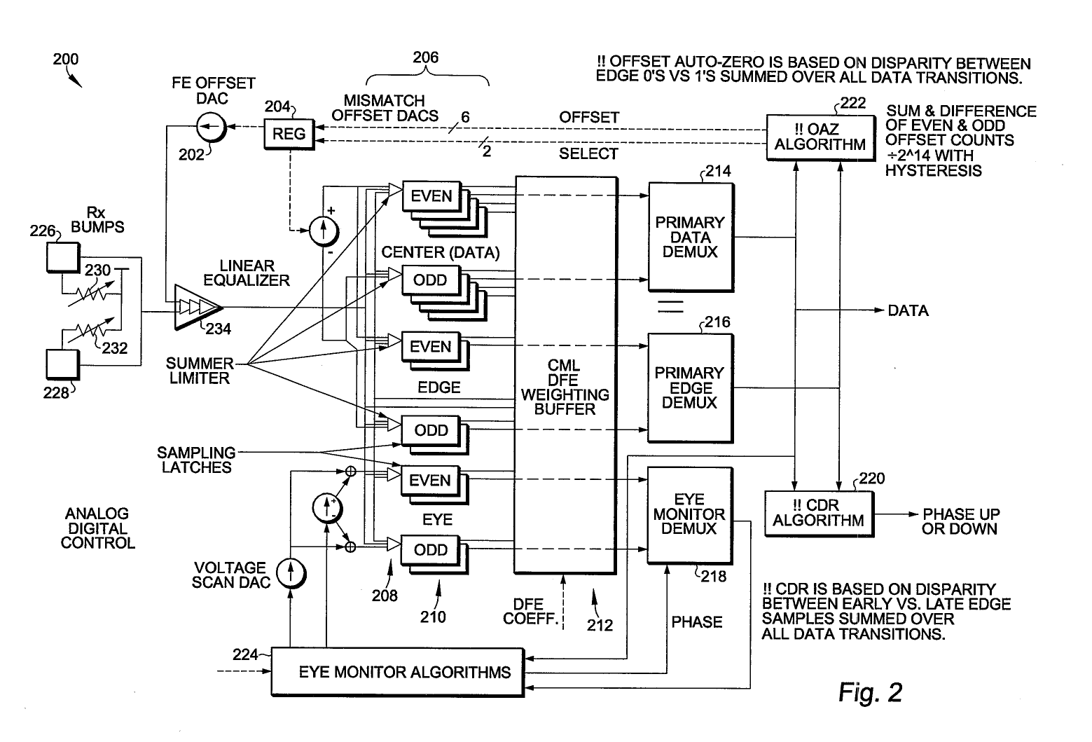

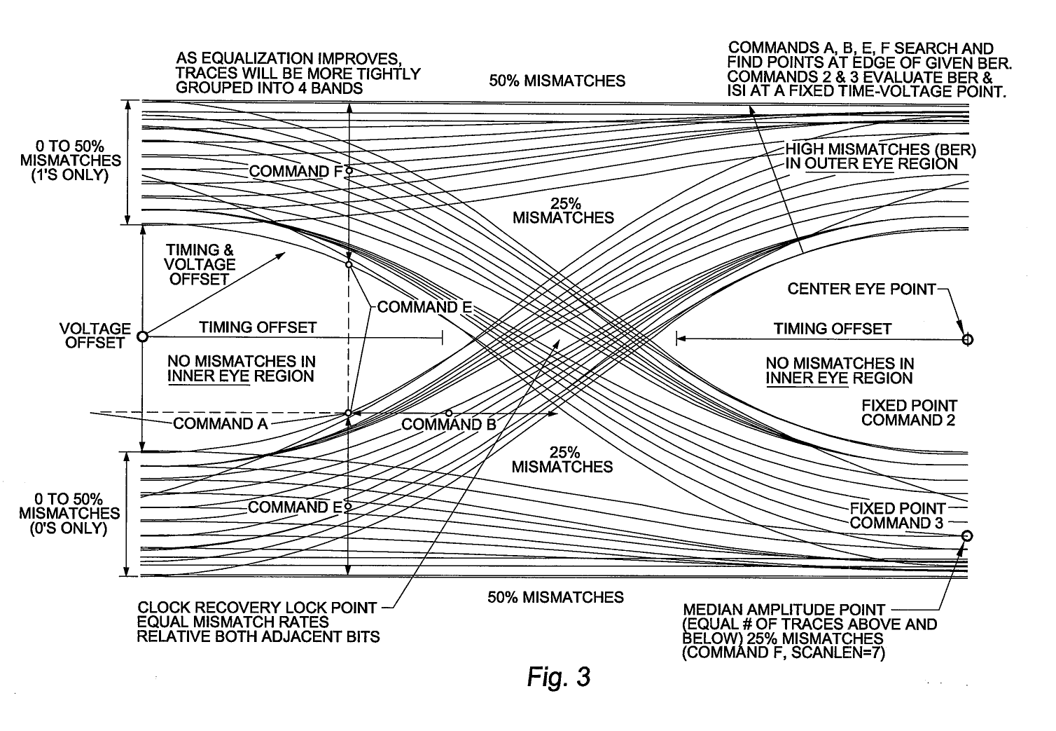

Referring now to FIG. 2, the “Top Level RX Architecture” diagram 200 shows key blocks in the receiver, including the primary offset compensation digital to analog converter (DAC) 202 labeled “FE Offset DAC” and another possible offset compensation DAC that is able to adjust offset difference between the edge and center samplers. Each DAC is driven from a digital register 204 that can be adjusted by manual commands as well as by the auto-zero algorithm. The block of circuitry 206 to the right of the DACs includes three pairs of limiting amplifiers 208 used to improve sampling resolution of the latches in the voltage domain, and three pairs of sampling latches 210, each marked as odd or even as explained below. The following large block 212 named “CML DFE weighting buffers” is not directly related to offset correction but is a critical part of the very important DFE (Decision Feedback Equalizer) circuitry. The “even” and “odd” markings refer to latches capturing data on the falling edges of the ½-bit-rate master clock vs. those capturing data alternately on the rising edges. This scheme allows use of a half-rate master clock and gives each latch twice the time to make its decision, which reduces power and improves performance, respectively. The first pair of latches captures center data by sampling near the middle of each eye, the second pair captures edge data by sampling near the signal crossover points, while the third “monitor” pair samples independently to measure any single or multiple set of specific points within the eye, or for use in determining correlations between samples taken at different points within the eye to extract various signal quality properties without affecting the recovered data and clock. The lines crossing-over between the first two pairs of limiting amplifiers indicate that the even pair are connected in parallel so they act as one, as are the odd pair. This avoids the need for separate offset correction for the center vs. the edge signal paths. The additional offset DAC is connected to apply a difference offset between the even vs. odd limiting amps as the even and odd paths carry different DFE equalization signals so cannot be connected in parallel.

The demux blocks 214, 216, 218 are simple serial-to-parallel converters that accumulate bits and output them as parallel words at a much lower rate for practical performance reasons. The center data parallel output and edge parallel output are compared and processed in the bang-bang CDR digital algorithm block 220 to maintain alignment of the master clock to the data, while the edge output is used by the bang-bang offset algorithm block 222 to maintain both the common voltage offset and the even/odd offset difference as close to zero as possible. The even or odd can be separately zeroed by the OAZ algorithm using only the even or odd bits, respectively. The eye monitor path has its own algorithms in block 224 that can determine offsets when needed.

The technique according to the present invention counts the balance of ‘0’ edge bits vs ‘1’ edge bits, and integrates the difference, then applies an incremental offset correction when the integral reaches some specific limit. Edge bits are those bits from the edge sampling channel lying between adjacent data bits of mutually opposite polarity. When the ‘1’ vs. ‘0’ count difference reaches a large pre-defined value, a minimum sized step of offset correction is applied to that channel or to the specific sampler involved. Only polarity information is needed, but proportional response near the ‘0’ offset condition always occurs due to noise and limited comparator gain. The CDR will automatically place the edge sampling point near signal crossover points where the edge samples miscorrelate equally with the data bits immediately before and after. Unless there is an amplitude dead-zone exactly where the CDR positions the edge sampler timing, any offset will immediately show up as a count difference which will be integrated and corrected.

If there is a dead-zone at the eye edge, i.e., at the median signal crossover position, the channel needs to be corrected because the CDR will then come to a satisfactory resting point anywhere within that dead-zone. This means it will be free to drift to any timing within that dead-zone rather than tracking the signal. Such a dead-zone would normally only occur with a very poorly equalized channel plus a large receive signal which will not occur simultaneously for acceptable channels. Poor equalization is needed to allow the eye to split into multiple sections, while a strong signal is required to prevent jitter, crosstalk, noise, etc., from causing those sections to merge into a continuous diffused crossover zone between full or partial eye openings. Such a dead-zone can be detected by the same offset compensation scheme by enabling the compensation and applying a small step of voltage offset (writing a slightly modified value to the offset register), first in one direction then in the other. If significantly different settled offset correction values are obtained, it indicates that a dead-band is present.

The receiver architecture 200 shown in FIG. 2 provides on-die differential and common mode termination, AGC, and an adaptive continuous-time linear equalizer filter—all these are in the common signal path. The sampling is in half-rate and the sampling thresholds of the decision circuits are the subject of local mismatch. In addition, the sampling is performed by two serial-parallel converters—one sampling at the center of the bit-periods, one sampling at the boundary between the bit-periods in order to sense the timing of the edge trajectories and provide synchronization to the sender's local time-reference and track the phase. One more serial-parallel converter is present, which most of the time is in powered-down. It is used as an ADC based under-sampling scope providing observation on the high-speed analog signal after being equalized at the input of the slicer before being sampled.

The RX “bumps” 226 and 228 are the equivalent of bonding pads in the “flip-chip” packaging technology. They are the terminals of the die—connecting it with the package =where the transmission lines of media and package get loaded by on-die termination impedance and where the analog signal processing path begins.

The termination resistors 230 and 232 have calibration functionality to cancel process and temperature factors on the reflection coefficient in the wide band of the signal spectrum.

The input to receiver 200 is an analog signal with up to 1 Vppd max swing; with spectral components in the band from data-rate/2 down to approaching 0 Hz, excluding the 0 Hz point.

The linear equalizer 234 and the DFE filter are part of the RX signal-processing, which equalizes the insertion loss of the media and the loss from reflections. The split signal path in the particular receiver architecture is an element which the proposed OAZ is able to cover.

The FE Offset DAC 202 is a feed-forward path that is the common signal path before the split, which contributes common offset and could be compensated right there in the feed-forward path or later after the split.

The mismatch offset DACs are used in case of cancelling only the offset difference after the split. This is like a single DAC, which steers DC components between the two signal paths. This means applying compensations with the same magnitude and opposite sign (half of the offset difference) in both split paths. This requires only one control bus driving two DACs—one of them inverting.

The CML DFE weighting buffers 212 are the scalers in the feed-back path of the DFE filter.

The Primary Data Demux 214 is the center sampling serial-parallel converter.

The Primary Edge Demux 216 is the edge sampling serial-parallel converter.

The Eye Monitor Demux 218 is an additional serial-parallel converter with an independently controlled sampling phase. It is used for adapting the RX equalization filtering.

The OAZ Algorithm block 222 is used for Offset-Auto-Zeroing (OAZ).

The CDR Algorithm block 220 is used for Clock-and-Data-Recovery (CDR).

The Eye Monitor Algorithms block 224 contains built-in algorithms for automatic control of the phase and offset in the independently sampling serial-parallel converter channel. These algorithms execute a set of macro-commands related to the eye-monitoring features. None of them is related to the proposed OAZ.

The OAZ circuit with the digital and analog elements has been implemented on test-silicon which supports back-plane media up to 1 m long at rates from 1.25 Gbps to 14.025 Gbps. The loss of the test-media goes up to −30 dB at 14 Gbps rate and requires good linearity in the large 1V input referred range for the RX analog processing which equalizes the loss. Before equalized, the lowest magnitudes are 30 mV on top of 1000 mV low frequency components. The offset cancellation is critical, the high-speed analog path has poor matching and it could generate static offset in the range of +/−100 mV (3-sigma input referred). The specification for the analog part of the OAZ functionality specifies the range needed to be covered by the DAC's full-scale and the resolution choice on the LSB.

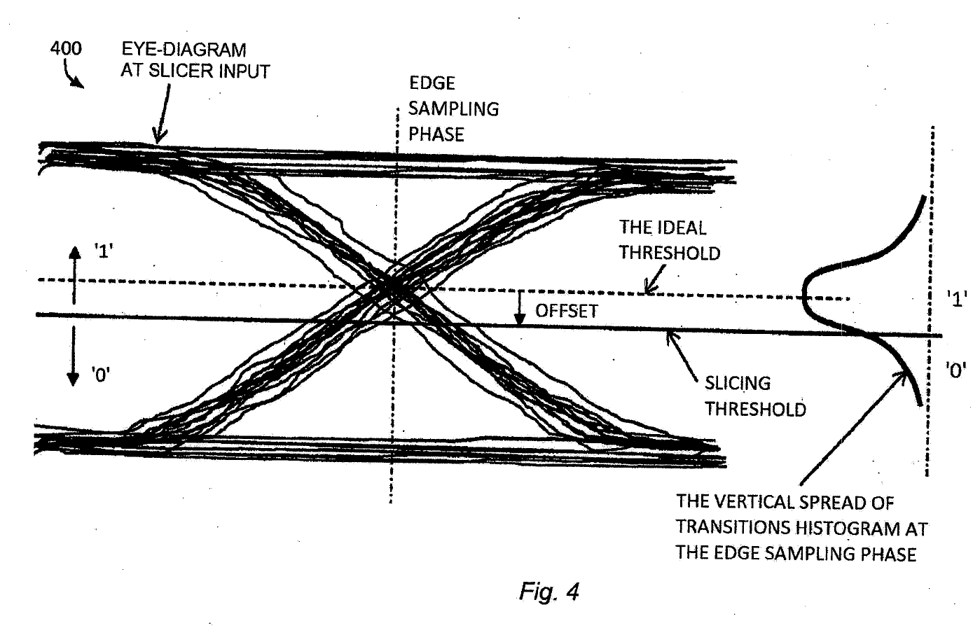

Referring now to FIG. 4, an eye diagram 400 is shown. The statistic of the vertical spread at the edge sampling phase carries the information for the offset by the imbalance relative to the slicing threshold. The slicer's non-linear operation gives very high sensititivity for the imbalance of sampled ‘1’ and ‘0’ states by its effectively infinite gain. Due to the limiting property, it also makes only the edge sampling phase carry information of the DC component. Counting the number of edge samples limited by the slicer to the state of ‘1’ and the samples limited by it to the state of ‘0’ gives the direction of imbalance by subtraction of both sums. Analogically to the “bang-bang” phase regulation, using only the sign for the direction of the imbalance the OAZ discrete regulation loop has the property to lock to the median of the edge-phase vertical histogram, where its balance is. This coincides with the actual cancellation of the DC component in the signal at the slicer's input (the edge-sampling one).

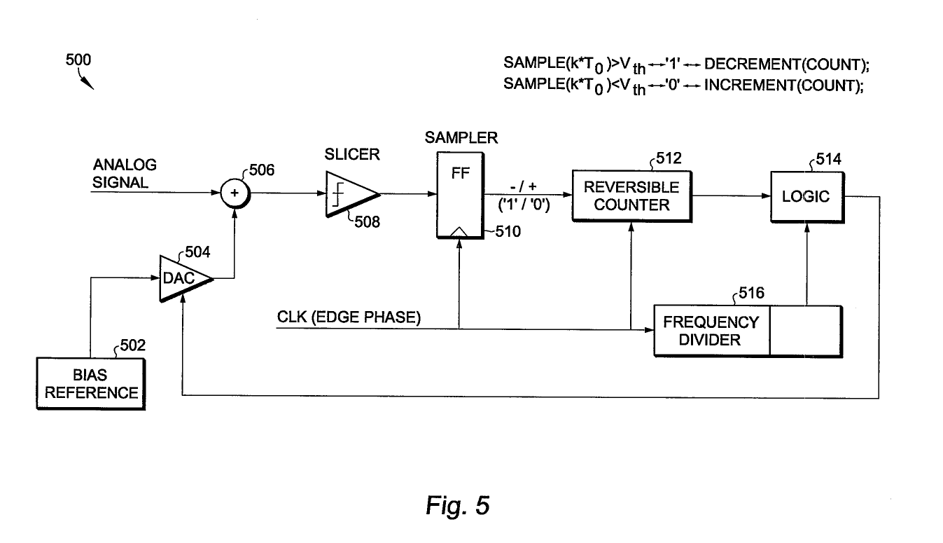

Referring now to FIG. 5, block diagram 500 includes a bias reference 502, DAC 504, summer 506, slicer 508, sampler 510, reversible counter 512, logic block 514, and frequency divider 516. The bias reference 502, slicer 508, sampler 510, and frequency divider 516 are part of the normal receiver circuit. The DAC 504, summer 506, reversible counter 512, and logic block 514 are added to build the loop of the non-linear OAZ regulator. The logic block 514 observes the resulted imbalance in the counts of sampled ‘0’ and ‘1’ states in chosen time-intervals of N-bits. And it increments/decrements the value of the current address in the scale of the OAZ DAC according to the sign of the count-imbalance. The logic could also implement hysteresis. The counter direction should organize negative feedback. The key detail is that the sampling clock is the one locked to the boundary between two bit intervals—the recovered edge sampling phase. The summer could be a resistor. The DAC could be simply a programmable static current source, such as a current mirror with programmable ratio to a reference.

It will be apparent to those skilled in the art, therefore that various modifications and variations can be made to the invention without departing from the spirit or scope of the invention. Thus, it is intended that the present invention covers the modifications and variations of this invention provided they come within the scope of the appended claims.

1. A non-linear offset regulator loop for a receiver comprising:
a summer for receiving an analog signal;
a slicer coupled to an output of the summer;
a sampler coupled to an output of the slicer;
a counter coupled an output of the amplifier;
a logic block coupled to an output of the counter;
a frequency divider coupled to the counter and the logic block; and
a DAC coupled to the summer and to the logic block.

2. The non-linear offset regulator loop according to claim 1 wherein the logic block comprises a buffer or register.

3. The non-linear offset regulator loop according to claim 1 wherein the logic block implements hysteresis by truncating division.

4. The non-linear offset regulator loop according to claim 1 further comprising a clock signal coupled to the sampler.

5. The non-linear offset regulator loop according to claim 4 wherein the clock signal is also coupled to the counter.

6. The non-linear offset regulator loop according to claim 5 wherein the clock signal is also coupled to the frequency divider.

7. The non-linear offset regulator loop according to claim 1 wherein the counter comprises a reversible counter.

8. The non-linear offset regulator loop according to claim 1 further comprising a bias reference coupled to the DAC.

9. The non-linear offset regulator loop according to claim 1 wherein the summer comprises a resistor.

10. The non-linear offset regulator loop according to claim 1 wherein the summer comprises a current mirror.

11. An offset cancellation method for a receiver comprising:
counting the balance of zero edge bits versus one edge bits;
integrating the difference; and
applying an incremental offset correction when the integral reaches a predetermined limit.

12. The offset cancellation method according to claim 11 wherein edge bits comprise those bits from an edge sampling channel lying between adjacent data bits of mutually opposite polarity.

13. The offset cancellation method of claim 11, wherein when the one versus the zero count difference reaches the predetermined value, a minimum sized step of offset correction is applied to a channel or to a specific sampler involved.

14. The offset cancellation method of claim 11 wherein only polarity information is required.

15. A receiver architecture comprising:
a linear equalizer;
a plurality of limiting amplifiers coupled to the linear equalizer;
a plurality of sampling latches coupled to the limiting amplifiers;
a filter coupled to the sampling latches;
a data demultiplexer coupled to the filter;
an auto-zero block coupled to the data demultiplexer; and
an offset compensation DAC coupled between the auto-zero block and the linear equalizer.

16. The receiver architecture of claim 15 further comprising an edge demultiplexer.

17. The receiver architecture of claim 15 further comprising an eye monitor demultiplexer.

18. The receiver architecture of claim 15 further comprising a CDR algorithm block.

19. The receiver architecture of claim 15 wherein the sampling latches comprise odd and even sampling latches.

20. The receiver architecture of claim 15 further comprises offset cancellation for counting the balance of zero edge bits versus one edge bits, integrating the difference, and applying an incremental offset correction when the integral reaches a predetermined limit.
